(19) United States
(12) Patent Application Publication
(10) Pub. No.: US 2025/0282557 A1
(43) Pub. Date: Sep. 11, 2025

(54) Article Transport Facility

(71) Applicant: Daifuku Co., Ltd., Osaka-shi (JP)

(72) Inventors: Makoto Kono, Komaki-shi (JP); Koichi Hagiwara, Komaki-shi (JP)

(21) Appl. No.: 19/071,177

(22) Filed: Mar. 5, 2025

(30) Foreign Application Priority Data
Mar. 6, 2024 (JP) 2024-034195

(51) Int. Cl. B65G 43/08; H01L 21/677

(52) U.S. Cl. CPC B65G 43/08; H01L 21/67724; H01L 21/6773; H01L 21/67733; B65G 2201/0297

(57) ABSTRACT

An article transport facility includes a plurality of transport vehicles and a control system. In order to select a target transport vehicle to be caused to perform transport processing from among transport vehicles not holding any article, the control system executes selection processing including calculating an evaluation cost for each of the transport vehicles not holding any article, using a cost whose value is related to a factor affecting the travel time of the corresponding transport vehicle and whose value increases as the travel time is longer, and selecting the transport vehicle having the smallest evaluation cost as the target transport vehicle. In the selection processing executed when a specific holding section is the transport origin, the control system calculates the evaluation cost based on both a receiving cost and a delivery cost.

### CROSS-REFERENCE TO RELATED APPLICATION

This application claims priority to Japanese Patent Application No. 2024-034195 filed Mar. 6, 2024, the disclosure of which is hereby incorporated by reference in its entirety.

### BACKGROUND OF THE INVENTION

### 1. Field of the Invention

The present invention relates to an article transport facility including a plurality of transport vehicles that move along a predetermined travel route to transport articles, and a control system that causes the transport vehicles to perform transport processing in which a transport origin and a transport destination have been designated for the articles.

### 2. Description of Related Art

For example, JP 2020-66499A discloses a transport system for use in a factory that manufactures a semiconductor product. In this transport system, in order to perform various types of processing on articles, the articles are transported between processing steps by transport vehicles. Typically, a system controller that manages the system issues a transport command, and, based on the transport command, a transport vehicle receives a designated article at a transport origin where the article is located, and transports the article to a designated transport destination.

When selecting which transport vehicle among a plurality of transport vehicles is to transport an article, in order to transport the article rationally from the viewpoint of the transport time and the like, the transport vehicle located closest to the location where the target article is stored (transport origin) is often selected. However, for example, when the route structure is complex or when there are constraints on the movement of the transport vehicles along a route, it can be possible for a transport vehicle that has received an article to travel along any of a plurality of routes to the transport destination, that is to say, a plurality of routes from the transport origin to the transport destination. Therefore, if the distance between the transport origin and the transport vehicle is used solely as the selection criterion for selecting a transport vehicle to transport an article, it may not be possible to transport the article rationally.

### SUMMARY OF THE INVENTION

In view of the above circumstances, there is a demand for an article transport facility that can realize the transport of articles in a highly rational manner.

The following is a technology for solving the foregoing problems.

An article transport facility according to an aspect of the present invention is an article transport facility including:
a plurality of transport vehicles configured to travel along a predetermined travel route and transport an article;
a control system configured to cause the plurality of transport vehicles to perform transport processing in which a transport origin and a transport destination are designated for respective articles; and
a plurality of article holding sections at respective locations along the travel route and configured to store articles and transfer articles with the plurality of transport vehicles,
at least one of the plurality of article holding sections being a specific holding section to and from which an article is transferable by a transport vehicle located in a specific zone among a plurality of specific zones on the travel route,
the control system being further configured to, in order to select a target transport vehicle to be caused to perform the transport processing from among a plurality of transport vehicles not holding any article, execute selection processing including (i) calculating an evaluation cost for each of the plurality of transport vehicles not holding any article, using a cost whose value is related to a factor affecting a travel time of the corresponding transport vehicle and whose value increases as the travel time is longer, and (ii) selecting a transport vehicle having a smallest evaluation cost as the target transport vehicle, and
in the selection processing executed in a case where the specific holding section is the transport origin, the control system calculates the evaluation cost based on both a receiving cost and a delivery cost, the receiving cost being the cost corresponding to a travel time from a current position of the corresponding transport vehicle to the transport origin, and the delivery cost being the cost corresponding to a travel time of the corresponding transport vehicle from the transport origin to the transport destination.

According to this configuration, when the specific holding section is set as the transport origin, the target transport vehicle to perform transport processing can be selected based on both the cost corresponding to the travel time from the current position of the transport vehicle to the transport origin and the cost corresponding to the travel time of the transport vehicle from the transport origin to the transport destination. In other words, the target transport vehicle can be selected based further on the situation after the transport vehicle receives the article at the transport origin. Therefore, with this configuration, it is possible to realize highly rational article transport.

Further features and advantages of the technology disclosed herein will become more apparent from the following description of exemplary and non-limiting embodiments described with reference to the drawings.

### BRIEF DESCRIPTION OF THE DRAWINGS

The terms Fig., Figs., Figure, and Figures are used interchangeably in the specification to refer to the corresponding figures in the drawings.

FIG. 1 is a plan view of an article transport facility.

FIG. 2 is a front view of an article holding section.

FIG. 3 is a front view of a specific holding section.

FIG. 4 is an illustrative diagram conceptually showing receiving costs and delivery costs.

FIG. 5 is an illustrative diagram showing evaluation costs calculated for respective transport vehicles.

FIG. 6 is a diagram showing a comparative example of evaluation costs for a transport vehicle A and a transport vehicle B.

FIG. 7 is a diagram showing another example of a specific zone.

### DESCRIPTION OF THE INVENTION

Hereinafter, an embodiment of an article transport facility will be described with reference to the drawings.

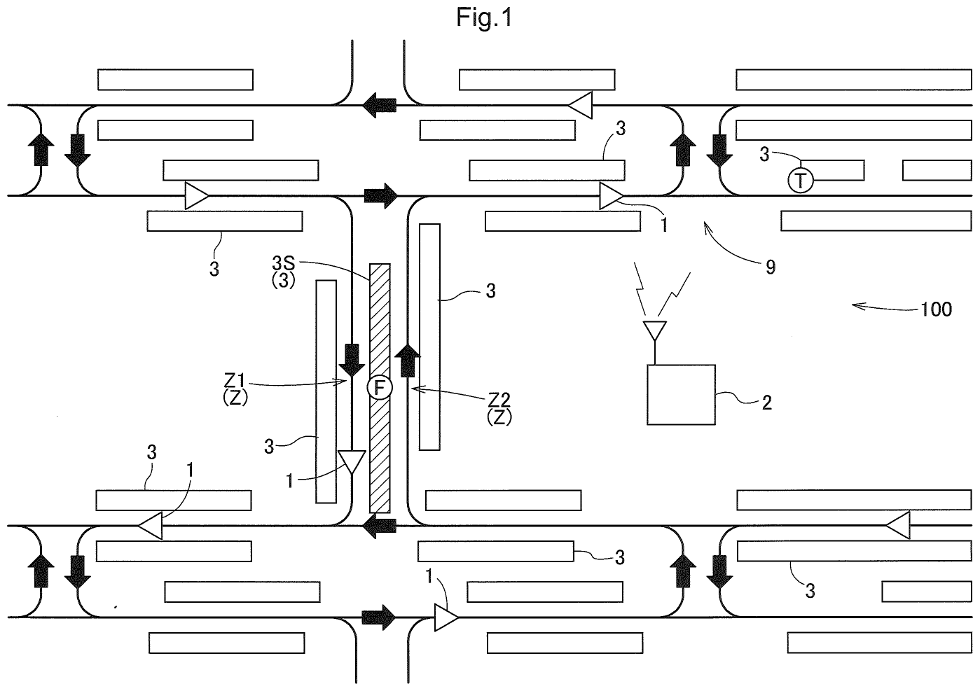

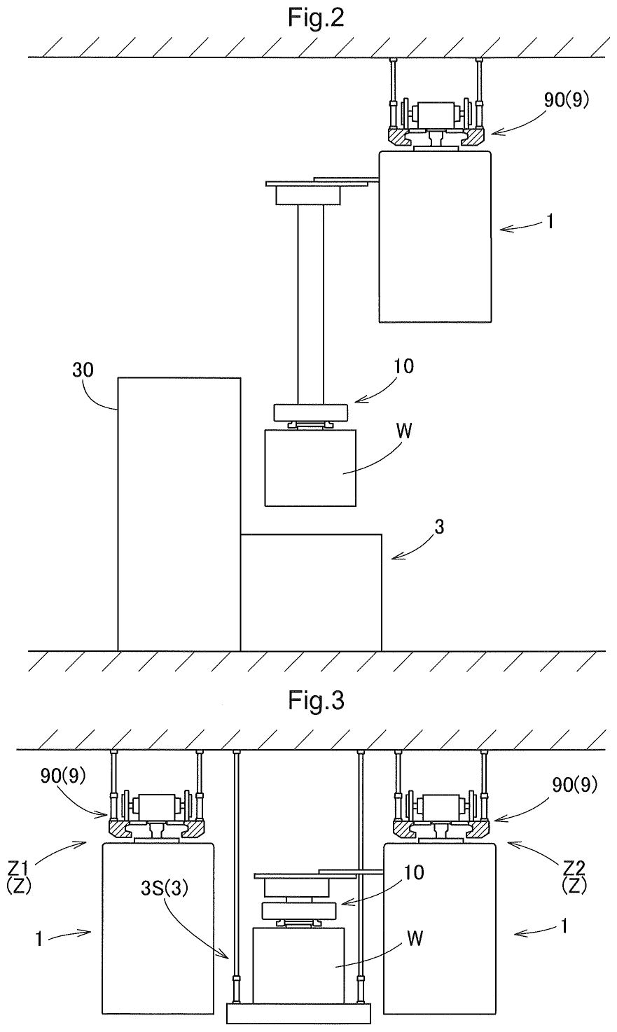

As shown in FIG. 1, an article transport facility 100 includes a plurality of transport vehicles 1 that move along a predetermined travel route 9 to transport articles W (see FIGS. 2 and 3), and a control system 2 that causes the transport vehicles 1 to perform transport processing in which a transport origin F and a transport destination T have been designated for the articles W.

In the present embodiment, the travel route 9 is set such that the travel directions of the transport vehicles 1 are fixed directions. In other words, the travel route 9 is a one-way route, and the transport vehicles 1 cannot travel backward.

As shown in FIGS. 2 and 3, in the present embodiment, the travel route 9 is set at a position distant above the floor surface. For example, the travel route 9 is configured using a rail 90 provided near the ceiling. The transport vehicles 1 are configured as so-called overhead transport vehicles, and travel on the rail 90 along the travel route 9.

Various types of articles W can be handled in the article transport facility 100. In the present embodiment, the article transport facility 100 is used in a semiconductor manufacturing factory. Examples of the article W include a substrate storage container (so-called FOUP: Front Opening Unified Pod) that store substrates such as wafers or panels, and a reticle storage container (so-called reticle pod) that stores reticles. In this case, the transport vehicles 1 transport the articles W, such as substrate storage containers or reticle storage containers, between processing steps along the travel route 9.

As shown in FIG. 1, article holding sections 3 that are capable of holding the articles W, and to and from which the transport vehicles 1 can transfer the articles W, are disposed at a plurality of locations along the travel route 9.

As shown in FIG. 2, in the present embodiment, each of the article holding sections 3 includes a load port adjacent to a processing device 30 that performs processing on the articles W. This processing performed on the articles W means processing performed on the stored object (substrate or reticle) contained in the article W serving as the storage container. The processing devices 30 perform various types of processing such as thin film formation, photolithography, and etching.

The transport vehicle 1 can receive an article W that has been processed by the processing device 30 from the article holding section 3, and deliver an article W that has not been processed by the processing device 30 to the article holding section 3. The transport vehicle 1 includes a gripping section 10 configured to be able to grip an article W, and is configured to transfer the article W between the gripping section 10 and the article holding section 3.

In the illustrated example, the load port serving as the article holding section 3 is disposed below the travel route 9 of the transport vehicle 1. The transport vehicle 1 transfers the article W between the article holding section 3 and the gripping section 10 by lifting and lowering the gripping section 10.

Also, as shown in FIG. 2, in the case where the article holding section 3 is offset laterally from the travel route 9 rather than being positioned directly below the travel route 9, the transport vehicle 1 positions the gripping section 10 directly above the article holding section 3 by sliding the gripping section 10 laterally from the vehicle body. Thereafter, the transport vehicle 1 transfers the article W between the article holding section 3 and the gripping section 10 by lifting and lowering the gripping section 10.

Furthermore, due to the structure of the article holding section 3, there may be constraints on the orientation of the article W to be placed in the article holding section 3. In such a case, the transport vehicle 1 changes the orientation of the article W held by the gripping section 10 by rotating the gripping section 10 about the vertical axis. Accordingly, the article W can be oriented in a proper orientation relative to the article holding section 3.

As described above, in the present embodiment, the transport vehicle 1 includes a slide mechanism for sliding the gripping section 10, a lifting mechanism for lifting and lowering the gripping section 10, and a turning mechanism for turning the gripping section 10. When an article W is being received or delivered, the time required for the receiving or delivering operation varies depending on whether or not the gripping section 10 is slid, lifted and lowered, or turned. Note that the above-mentioned receiving and delivering operation can also be called a “transfer operation”.

As shown in FIG. 1, at least one of the article holding sections 3 is a specific holding section 3S to and from which an article W can be transferred by a transport vehicle 1 located in any of a plurality of specific zones Z on the travel route 9.

The specific zones Z include a first specific zone Z1 and a second specific zone Z2 that are next to each other. Here “next to each other” means that the first specific zone Z1 and the second specific zone Z2 are arranged side by side in a manner other than a manner in which they are continuous with each other along the direction in which the travel route 9 extends. Therefore, the first specific zone Z1 and the second specific zone Z2 do not need to be parallel with each other. In this example, the first specific zone Z1 and the second specific zone Z2 are arranged side by side in the left-right direction.

In the present embodiment, the travel direction of the transport vehicle 1 permitted in the first specific zone Z1 and the travel direction of the transport vehicle 1 permitted in the second specific zone Z2 are set different from each other. In the example shown in FIG. 1, in the first specific zone Z1, the transport vehicle 1 is permitted to move only downward in the figure. In the second specific zone Z2, the transport vehicle 1 is permitted to move only upward in the figure.

In this manner, the first specific zone Z1 and the second specific zone Z2 are next to each other, and are zones in which the permitted travel directions of the transport vehicle 1 are different from each other. However, when the travel route 9 is viewed as a whole, the first specific zone Z1 and the second specific zone Z2 are connected such that the transport vehicle 1 can travel between them via a connection zone. Any route included in the travel route 9 that can connect the first specific zone Z1 and the second specific zone Z2 to each other can be a connection zone.

As shown in FIG. 3, in the present embodiment, the specific holding section 3S includes a buffer for temporarily storing the articles W. In the illustrated example, a buffer serving as the specific holding section 3S is disposed between the first specific zone Z1 and the second specific zone Z2. This specific holding section 3S can be accessed by both the transport vehicle 1 located in the first specific zone Z1 and the transport vehicle 1 located in the second specific zone Z2. In other words, the articles W can be transferred between the specific holding section 3S and any of the transport vehicles 1.

As shown in FIG. 1, the control system 2 is configured to cause the transport vehicles 1 to perform transport processing. In this example, a host control device that performs overall control of the transport vehicles 1 constitutes the control system 2. However, in a broad sense, the control system 2 is constituted by various control devices in the article transport facility 100. For example, transport vehicle control devices (not shown) provided in the transport vehicles 1 may constitute a part or the whole of the control system 2.

The control system 2 includes, for example, a processor such as a microcomputer, and a peripheral circuit such as a memory. Processing and functions are realized by cooperation between the hardware and a program executed on the processor of a computer or the like.

In the transport processing that the control system 2 causes a transport vehicle 1 to perform, a transport origin F where an article W is held and a transport destination T of the article W are designated. At that time, the control system 2 also designates a route from the transport origin F to the transport destination T. The control system 2 can extract a plurality of routes, select an optimal route (the route that minimizes the total time required from when a transport command is issued to when the transport processing is completed) from among the extracted routes, and designate the optimal route for the transport vehicle 1. In executing the transport processing, the transport vehicle 1 moves to the transport origin F to receive an article W, and transports the received article W to the transport destination T and delivers the article W there. The control system 2 is configured to execute selection processing for selecting a target transport vehicle 1, which is the transport vehicle 1 to be caused to perform transport processing, from among a plurality of transport vehicles 1 that are not holding an article W.

Here, since there are a plurality of transport vehicles 1 on the travel route 9, each of the transport vehicles 1 is a candidate for selection as the target transport vehicle 1. The travel route 9 from each of the transport vehicles 1 to the transport origin F varies depending on the current position of the transport vehicle 1. In other words, there are a plurality of travel routes 9 from the transport vehicles 1 to the transport origin F.

However, in the case where an article holding section 3 other than the specific holding section 3S is the transport origin F, the travel route 9 after the transport vehicle 1 receives the article W at the transport origin F, that is to say, the travel route 9 from the transport origin F to the transport destination T, is the same regardless of which transport vehicle 1 is selected as the target transport vehicle 1. This is because, as described above, one-way travel is performed along the travel route 9, and a rational travel route 9 from the article holding section 3 (transport origin F) to the transport destination T is easy to determine uniquely.

In the case where the specific holding section 3S is the transport origin F, the travel route 9 from the transport origin F to the transport destination T also differs depending on which transport vehicle 1 is selected as the target transport vehicle 1. In other words, since the permitted travel direction of the transport vehicle 1 is different between the first specific zone Z1 and the second specific zone Z2, when the transport vehicle 1 in the first specific zone Z1 receives an article W from the specific holding section 3S (transport origin F), the subsequent travel route 9 to the transport destination T is different from when the transport vehicle 1 in the second specific zone Z2 receives the article W from the specific holding section 3S (transport origin F).

In view of the above-described circumstances, selection processing is executed to select a target transport vehicle 1 that is to execute the transport processing.

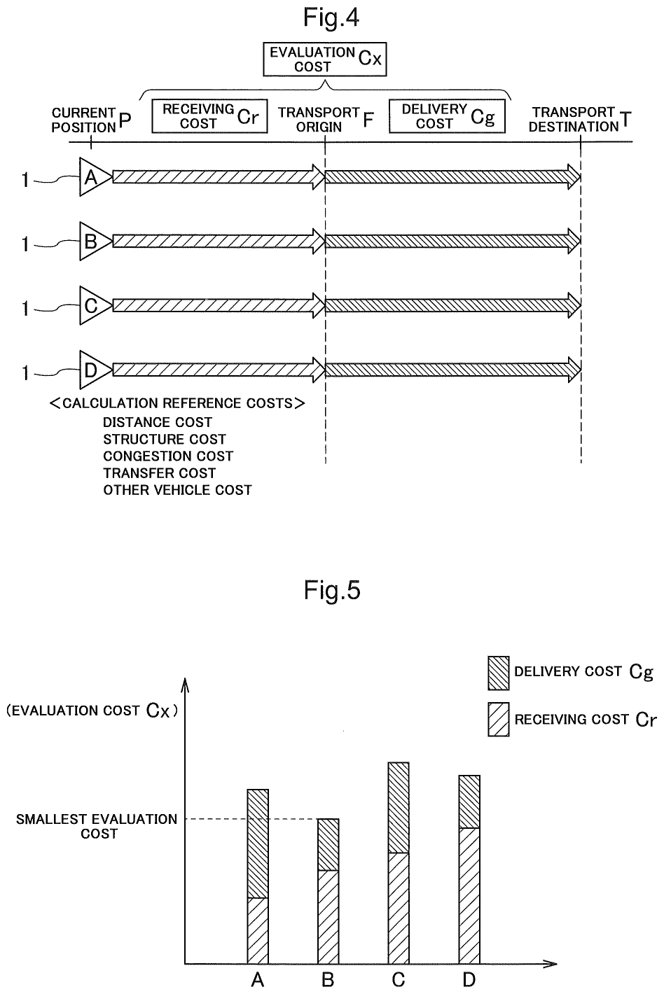

As shown in FIG. 4, by executing selection processing, the control system 2 calculates an evaluation cost Cx for each transport vehicle 1 using costs C, which are values regarding factors that affect the travel time of the transport vehicle 1 and increase as the travel time becomes longer, and selects a target transport vehicle 1 based on the evaluation cost Cx.

In selection processing in the case where the specific holding section 3S is the transport origin F, the evaluation cost Cx is calculated based on both a receiving cost Cr, which is a cost C corresponding to the travel time of the transport vehicle 1 from a current position P to the transport origin F, and a delivery cost Cg, which is a cost C corresponding to the travel time of the transport vehicle 1 from the transport origin F to the transport destination T. Note that the receiving cost Cr and the delivery cost Cg are both calculated by adding a variable cost, which is calculated taking into account the presence of other transport vehicles 1 on the route at the present time or in the future, to a reference cost calculated on the assumption that there are no other transport vehicles 1 on the route. Furthermore, when a route is defined by one or more links, the reference cost and variable cost can be calculated for each of the links.

FIG. 4 is a diagram conceptually showing the receiving cost Cr and the delivery cost Cg. FIG. 4 also illustrates four transport vehicles A to D, with each transport vehicle 1 having a different current position P.

The receiving cost Cr and the delivery cost Cg are calculated as quantitative values to facilitate comparison between the transport vehicles A to D.

Factors that affect the travel time of the transport vehicle 1 include, for example, the travel distance of the transport vehicle 1, the structure of the travel route 9, congestion on the travel route 9, the time required for the transfer of the article W, and the number of other transport vehicles 1 on the travel route 9. The costs C are set to increase as the travel time of the transport vehicle 1 increases due to such factors. In the present embodiment, the receiving cost Cr and the delivery cost Cg are calculated using at least one of the following: a distance cost, which increases as the travel distance of the transport vehicle 1 becomes longer; a structure cost, which increases as the maximum travel speed of the transport vehicle 1 decreases according to the structure of the travel route 9 of the transport vehicle 1; a congestion cost, which increases as the degree of congestion on the travel route 9 of the transport vehicle 1 increases; a transfer cost, which increases as the time it takes for the transport vehicle 1 to transfer the article W between the article holding section 3 and the transport destination T becomes longer; and an other vehicle cost, which increases as the number of other transport vehicles 1 present on the travel route 9 of the transport vehicle 1 increases.

The distance cost is determined according to the length of the travel distance of the transport vehicle 1. In other words, the distance cost required from the current position P of the transport vehicle 1 to the transport origin F is determined according to the length of the travel route 9 from the current position P of the transport vehicle 1 to the transport origin F. Also, the distance cost required from the transport origin F to the transport destination T is determined according to the length of the travel route 9 from the transport origin F to the transport destination T. The longer the travel distance is, the longer the travel time of the transport vehicle 1 is, and therefore the distance cost becomes relatively larger.

The structure cost is determined according to the structure of the travel route 9. For example, in a straight line portion of the travel route 9, the maximum travel speed of the transport vehicle 1 is likely to be set higher, the travel time of the transport vehicle 1 is accordingly shorter, and thus the structure cost is relatively smaller. On the other hand, in a curved portion of the travel route 9 and at a junction portion where multiple travel routes 9 join, the maximum travel speed of the transport vehicle 1 is likely to be set lower, the travel time of the transport vehicle 1 is according longer, and thus the structure cost is relatively larger.

The congestion cost is determined according to the degree of congestion (congestion level) on the travel route 9. The higher the congestion level is, the longer the travel time of the transport vehicle 1 is, and therefore the congestion cost becomes relatively larger. The congestion level is set according to, for example, the number of transport vehicles 1 in a predetermined section of the travel route 9, the passing speed or the passing time of the transport vehicles 1, and the like. The congestion level may also be set based on the length of the congestion. The length of the congested may be the length of congestion that actually exists on the travel route 9, or the length of congestion that does not currently exist but is predicted to occur in the future.

The transfer cost is determined according to the time taken for the transport vehicle 1 to transfer the article W. As described above, in the present embodiment, the transport vehicle 1 includes a slide mechanism for sliding the gripping section 10, a lifting mechanism for lifting and lowering the gripping section 10, and a turning mechanism for turning the gripping section 10. When an article W is delivered or received, the time required for the transfer operation varies depending on whether the gripping section 10 is slid and the amount of sliding, whether it is lifted or lowered and the amount of lifting or lowering, and whether it is turned and the amount of turning. The longer the time required for the transfer operation is, the longer the travel time of the transport vehicle 1 is, and therefore the transfer cost becomes relatively higher.

The other vehicle cost is determined according to the number of other transport vehicles 1 that are present on the travel route 9. The movement of a transport vehicle 1 is constrained by the presence of other transport vehicles. As the number of other transport vehicles 1 increases, the number of constraints also increases, the travel time tends to accordingly become longer, and thus the other vehicle cost becomes relatively higher. Furthermore, the number of other transport vehicles 1 may be the number of other transport vehicles 1 that are actually present, or the number of other transport vehicles 1 that may be present in the future.

At least one of the distance cost, the structure cost, the congestion cost, the transfer cost, and the other vehicle cost is used to calculate the receiving cost Cr and the delivery cost Cg. These five costs can be called “element costs”, and the receiving cost Cr and the delivery cost Cg are calculated by, for example, adding element costs together, multiplying element costs together, or by a combination of these. In selection processing in the case where the specific holding section 3S is set as the transport origin F, the control system 2 calculates the evaluation cost Cx based on both the calculated receiving cost Cr and the calculated delivery cost Cg.

Note that in selection processing in the case where an article holding section 3 other than the specific holding section 3S is set as the transport origin F, the evaluation cost Cx is calculated based on the receiving cost Cr, which is the cost C corresponding to the travel time from the current position P of the transport vehicle 1 to the transport origin F. In other words, the delivery cost Cg is not taken into consideration. The reason for this is that, as described above, the travel route 9 from the transport origin F to the transport destination T is the same regardless of which transport vehicle 1 is selected as the target transport vehicle 1.

FIG. 5 shows the evaluation cost Cx for each of the transport vehicles A to D.

By executing selection processing, the control system 2 calculates the evaluation cost Cx for each transport vehicle 1, and selects the transport vehicle 1 with the smallest evaluation cost Cx as the target transport vehicle 1. In the present embodiment, the evaluation cost Cx is calculated for each transport vehicle 1 by adding up the receiving cost Cr and the delivery cost Cg. The control system 2 compares the evaluation costs Cx calculated for the transport vehicles 1 to determine the smallest evaluation cost that results in the lowest evaluation cost Cx, and selects the transport vehicle 1 associated with the smallest evaluation cost as the target transport vehicle 1.

In the example shown in FIG. 5, the evaluation cost Cx for the transport vehicle B is the smallest evaluation cost, and therefore the control system 2 selects the transport vehicle B as the target transport vehicle 1.

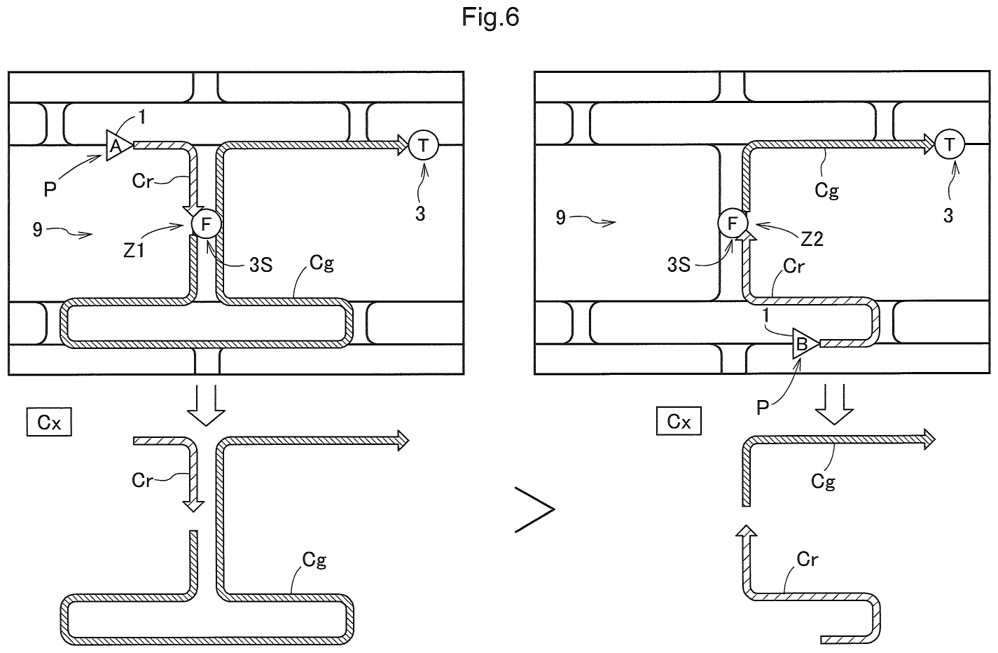

FIG. 6 illustrates an example in which, in selection processing in the case where the specific holding section 3S is set as the transport origin F, the evaluation cost Cx is calculated using only the distance cost. The evaluation costs Cx of the transport vehicle A and the transport vehicle B, which are at different current positions P, will be compared with reference to FIG. 6.

In the example shown in FIG. 6, the current position P of the transport vehicle A is closer to the transport origin F than the current position P of the transport vehicle B is. Therefore, the receiving cost Cr of the transport vehicle A is smaller than that of the transport vehicle B. In the selection processing, if only the travel route 9 from the current position P of the transport vehicle 1 to the transport origin F is taken into consideration, the transport vehicle A that has the smallest receiving cost Cr is selected as the target transport vehicle 1.

However, since the specific holding section 3S is the transport origin F, the travel route 9 from the first specific zone Z1 to the transport destination T in the case where the transport vehicle A receives the article W is different from the travel route 9 from the second specific zone Z2 to the transport destination T in the case where the transport vehicle B receives the article W. Therefore, the delivery cost Cg of each of the transport vehicle A and the transport vehicle B must also be taken into consideration.

In the example shown in FIG. 6, the travel route 9 from the second specific zone Z2 to the transport destination T in the case where the transport vehicle B receives the article W is shorter than the travel route 9 from the first specific zone Z1 to the transport destination T in the case where the transport vehicle A receives the article W. Therefore, the delivery cost Cg of the transport vehicle B is smaller than that of the transport vehicle A.

In the present embodiment, the evaluation cost Cx is calculated by adding up the receiving cost Cr and the delivery cost Cg for each transport vehicle 1.

In the example shown in FIG. 6, the evaluation cost Cx (receiving cost Cr +delivery cost Cg) for the transport vehicle B is smaller than the evaluation cost Cx (receiving cost Cr +delivery cost Cg) for the transport vehicle A. Therefore, the control system 2 selects the transport vehicle B as the target transport vehicle 1 in the selection processing. Accordingly, the transport of the article W from the transport origin F to the transport destination T can be rationally performed using the transport vehicle B.

### Other Embodiments

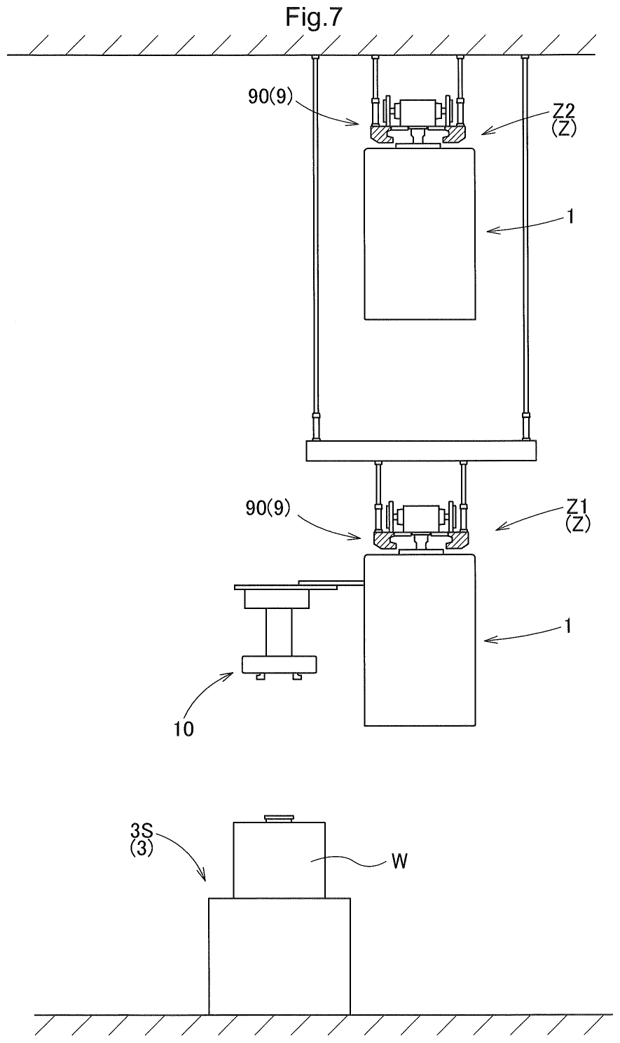

Next, other embodiments will be described.
(1) In the above embodiment, an example has been described in which the first specific zone Z1 and the second specific zone Z2 are side by side in the left-right direction. However, the present invention is not limited to such an example, and the first specific zone Z1 and the second specific zone Z2 need only be arranged side by side in a manner other than a manner in which they are continuous with each other along the direction in which the travel route 9 extends. Therefore, for example, as shown in FIG. 7, in a portion where a plurality of travel routes 9 exist along the vertical direction, the first specific zone Z1 and the second specific zone Z2 may be side by side in the up-down direction. In this case, both the transport vehicle 1 in the first specific zone Z1 and the transport vehicle 1 in the second specific zone Z2 can transfer an article W with the article holding section 3 located below both the first specific zone Z1 and the second specific zone Z2. Therefore, such an article holding section 3 is also considered to be a specific holding section 3S.
(2) In the above embodiment, an example has been described in which the travel direction

of the transport vehicle 1 permitted in the first specific zone Z1 and the travel direction of the transport vehicle 1 permitted in the second specific zone Z2 are set different from each other. However, the present invention is not limited to such an example, and these travel directions may be set to the same direction.
(3) In the above embodiment, an example has been described in which the evaluation cost Cx is calculated by adding up the receiving cost Cr and the delivery cost Cg for each transport vehicle 1. However, the present invention is not limited to such an example, and the evaluation cost Cx may be calculated by, for example, multiplying the receiving cost Cr and the delivery cost Cg.
(4) In the above embodiment, an example has been described in which the evaluation cost Cx of the transport vehicle 1 is calculated based on three locations, namely the current position P of the transport vehicle 1, the transport origin F, and the transport destination T. However, the evaluation cost Cx may be calculated additionally based on a fourth location that the transport vehicle 1 can travel to, for example. An example of the fourth location is a maintenance station where maintenance, inspection, and the like are performed on the transport vehicle 1. If the transport vehicle 1 needs repair or charging, the transport vehicle 1 travels to the maintenance station (fourth location) after completing transport processing. The calculation of the evaluation cost Cx also takes into consideration the cost required for the transport vehicle 1 to travel to the maintenance station.
(5) In the above embodiment, an example has been described in which the travel route 9 is configured using the rail 90 provided near the ceiling. However, the present invention is not limited to such an example, and a configuration is possible in which the travel route 9 is configured using a rail disposed near the floor surface, and the transport vehicle 1 is configured to move along the rail. Alternatively, a configuration is possible in which the travel route 9 is configured using magnetic tape disposed on the floor surface, and the transport vehicle 1 is configured to travel along the magnetic tape.
(6) Note that the configurations disclosed in the above-described embodiments may be combined with configurations disclosed in other embodiments as long as no contradiction arises. Regarding such other configurations as well, the embodiments disclosed in this specification are merely examples in all respects. Therefore, various modifications can be made as appropriate within the scope of the present disclosure.

### Overview of Present Embodiment

The following is an overview of the present embodiment.

An article transport facility according to an aspect of the present invention is an article transport facility including:
a plurality of transport vehicles configured to travel along a predetermined travel route and transport an article;
a control system configured to cause the plurality of transport vehicles to perform transport processing in which a transport origin and a transport destination are designated for respective articles; and
a plurality of article holding sections at respective locations along the travel route and configured to store articles and transfer articles with the plurality of transport vehicles,
at least one of the plurality of article holding sections being a specific holding section to and from which an article is transferable by a transport vehicle located in a specific zone among a plurality of specific zones on the travel route,
the control system being further configured to, in order to select a target transport vehicle to be caused to perform the transport processing from among a plurality of transport vehicles not holding any article, execute selection processing including (i) calculating an evaluation cost for each of the plurality of transport vehicles not holding any article, using a cost whose value is related to a factor affecting a travel time of the corresponding transport vehicle and whose value increases as the travel time is longer, and (ii) selecting a transport vehicle having a smallest evaluation cost as the target transport vehicle, and
in the selection processing executed in a case where the specific holding section is the transport origin, the control system calculates the evaluation cost based on both a receiving cost and a delivery cost, the receiving cost being the cost corresponding to a travel time from a current position of the corresponding transport vehicle to the transport origin, and the delivery cost being the cost corresponding to a travel time of the corresponding transport vehicle from the transport origin to the transport destination.

According to this configuration, when the specific holding section is set as the transport origin, the target transport vehicle to perform transport processing can be selected based on both the cost corresponding to the travel time from the current position of the transport vehicle to the transport origin and the cost corresponding to the travel time of the transport vehicle from the transport origin to the transport destination. In other words, the target transport vehicle can be selected based further on the situation after the transport vehicle receives the article at the transport origin. Therefore, with this configuration, it is possible to realize highly rational article transport.

It is preferable that in the selection processing executed in a case where an article holding section other than the specific holding section is the transport origin, the control system calculates the evaluation cost based on the receiving cost, which is the cost corresponding to the travel time from the current position of the corresponding transport vehicle to the transport origin.

For example, in the case where the travel direction of the transport vehicles on the travel route is limited to one direction and an article holding section other than a specific holding section is set as the transport origin, the travel route to the transport destination (travel route from the transport origin to the transport destination) after the transport vehicle receives the article at the transport origin is the same regardless of which transport vehicle is selected. In such a case, there is little need to use the delivery cost when calculating the evaluation cost. According to this configuration, in selection processing in the case where an article holding section other than a specific holding section is set as the transport origin, the evaluation cost is calculated based on the receiving cost, and therefore the delivery cost can be excluded from the calculation elements, thereby making it possible to reduce the computational load on the control system.

It is preferable that the plurality of specific zones include a first specific zone and a second specific zone that are next to each other,
the plurality of transport vehicles are permitted to travel in a first travel direction in the first specific zone and permitted to travel in a second travel direction different from the first travel direction in the second specific zone, and
the first specific zone and the second specific zone are connected in such a manner that the plurality of transport vehicles can travel between the first specific zone and the second specific zone via a connection zone.

The travel route for arriving at the specific holding section differs depending on whether the transport vehicle passes through the first specific zone or the second specific zone, and it is highly likely that the travel route from the specific holding section to the transport destination will also differ. However, as described above, the evaluation cost, which serves as an indicator for selecting the target transport vehicle, is calculated based on both the receiving cost corresponding to the travel route of the transport vehicle to the specific holding section, and the delivery cost corresponding to the travel route from the specific holding section to the transport destination. Therefore, even when the first specific zone and the second specific zone are provided on the travel route as in this configuration, the control system can select the most suitable transport vehicle as the target transport vehicle.

It is preferable that the receiving cost and the delivery cost are calculated using at least one of a distance cost, a structure cost, a congestion cost, a transfer cost, and an other vehicle cost,
the distance cost being a cost that increases as a travel distance of the corresponding transport vehicle increases,
the structure cost being a cost that increases as a maximum travel speed of the corresponding transport vehicle decreases according to a structure of the travel route traveled by the corresponding transport vehicle,
the congestion cost being a cost that increases as a congestion level in the travel route traveled by the corresponding transport vehicle increases,
the transfer cost being a cost that increases as a transfer time increases, the transfer time being a time required for the corresponding transport vehicle to perform article transfer with the article holding section and perform article transfer at the transport destination, and
the other vehicle cost being a cost that increases as a total number of other transport vehicles in the travel route traveled by the corresponding transport vehicle increases.

According to this configuration, various costs can be appropriately determined based on various factors that affect the travel time of the transport vehicle. Since these costs are used in calculating the receiving cost and the delivery cost, and thus used in calculating the evaluation cost, it is possible to appropriately select the target transport vehicle.

### INDUSTRIAL APPLICABILITY

The technology disclosed herein is applicable to an article transport facility including a plurality of transport vehicles that move along a predetermined travel route to transport articles, and a control system that causes the transport vehicles to perform transport processing in which a transport origin and a transport destination have been designated for the articles.

What is claimed is:

1. An article transport facility comprising:
a plurality of transport vehicles configured to travel along a predetermined travel route and transport an article;
a control system configured to cause the plurality of transport vehicles to perform transport processing in which a transport origin and a transport destination are designated for respective articles; and
a plurality of article holding sections at respective locations along the travel route and configured to store articles and transfer articles with the plurality of transport vehicles, and
wherein:
at least one of the plurality of article holding sections is a specific holding section to and from which an article is transferable by a transport vehicle located in a specific zone among a plurality of specific zones on the travel route,
the control system is further configured to, in order to select a target transport vehicle to be caused to perform the transport processing from among a plurality of transport vehicles not holding any article, execute selection processing comprising (i) calculating an evaluation cost for each of the plurality of transport vehicles not holding any article, using a cost whose value is related to a factor affecting a travel time of the corresponding transport vehicle and whose value increases as the travel time is longer, and (ii) selecting a transport vehicle having a smallest evaluation cost as the target transport vehicle, and
in the selection processing executed in a case where the specific holding section is the transport origin, the control system calculates the evaluation cost based on both a receiving cost and a delivery cost, the receiving cost is the cost corresponding to a travel time from a current position of the corresponding transport vehicle to the transport origin, and the delivery cost is the cost corresponding to a travel time of the corresponding transport vehicle from the transport origin to the transport destination.

2. The article transport facility according to claim 1,
wherein in the selection processing executed in a case where an article holding section other than the specific holding section is the transport origin, the control system calculates the evaluation cost based on the receiving cost, which is the cost corresponding to the travel time from the current position of the corresponding transport vehicle to the transport origin.

3. The article transport facility according to claim 1, wherein:
the plurality of specific zones comprise a first specific zone and a second specific zone that are next to each other,
the plurality of transport vehicles is permitted to travel in a first travel direction in the first specific zone and permitted to travel in a second travel direction different from the first travel direction in the second specific zone, and
the first specific zone and the second specific zone are connected in such a manner that the plurality of transport vehicles can travel between the first specific zone and the second specific zone via a connection zone.

4. The article transport facility according to claim 1, wherein:
the receiving cost and the delivery cost are calculated using at least one of a distance cost, a structure cost, a congestion cost, a transfer cost, and an other vehicle cost,
the distance cost is a cost that increases as a travel distance of the corresponding transport vehicle increases,
the structure cost is a cost that increases as a maximum travel speed of the corresponding transport vehicle decreases according to a structure of the travel route traveled by the corresponding transport vehicle,
the congestion cost is a cost that increases as a congestion level in the travel route traveled by the corresponding transport vehicle increases,
the transfer cost is a cost that increases as a transfer time increases, and the transfer time is a time required for the corresponding transport vehicle to perform article transfer with the article holding section and perform article transfer at the transport destination, and
the other vehicle cost is a cost that increases as a total number of other transport vehicles in the travel route traveled by the corresponding transport vehicle increases.
